(19) United States
(12) Patent Application Publication
(10) Pub. No.: US 2026/0073991 A1
(43) Pub. Date: Mar. 12, 2026

(54) STORAGE DEVICE

(71) Applicant: SK hynix Inc., Icheon-si (KR)

(72) Inventors: Seung Gu JI, Icheon-si (KR); Dong Jae Shin, Icheon-si (KR)

(21) Appl. No.: 19/036,892

(22) Filed: Jan. 24, 2025

(30) Foreign Application Priority Data
Sep. 11, 2024 (KR) 10-2024-0123590

(51) Int. Cl. G11C 16/10; G11C 16/32; G11C 16/34

(52) U.S. Cl. CPC G11C 16/102; G11C 16/32; G11C 16/3459

(57) ABSTRACT

A storage device is capable of reducing the time required for a program operation, improving the efficiency of the program operation, and preventing the reliability of the program operation from being reduced by selectively performing a program operation without a verification operation or performing the program operation while performing the verification operation on a memory area included in a designated storage block of the memory.

### CROSS-REFERENCE TO RELATED APPLICATION

The present application claims priority under 35 U.S.C. 119(a) to Korean patent application number 10-2024-0123590 filed on Sep. 11, 2024, which is incorporated herein by reference in its entirety.

### TECHNICAL FIELD

The embodiments of the present disclosure relate to a storage device.

### BACKGROUND

A storage device may include at least one memory for storing data. The storage device may include a controller for controlling the operation of at least one memory.

The controller may control, for example, an operation of writing data to the memory. The controller may control an operation of reading or erasing data written to the memory.

In some cases, data according to the writing operation may not be normally written to the memory, and a verification operation may be performed to confirm whether the data is normally written.

### SUMMARY

Embodiments of the disclosure may provide a storage device capable of maintaining the reliability of the operation of writing data to the storage device, improving the performance of the writing operation, and increasing the efficiency of power consumption.

Embodiments of the disclosure may provide a storage device including a memory including a plurality of storage blocks, each of the plurality of storage blocks including a plurality of word lines, a plurality of bit lines, and a plurality of memory cells, and a controller configured to control a program operation for the memory, wherein, in a first period during which a program operation is performed on a first memory cell connected to a first word line and a first bit line included in a first storage block among the plurality of storage blocks, a program voltage is applied to the first memory cell, and the program operation on the first memory cell completes without a verification voltage being applied to the first memory cell, and wherein, in a second period during which a program operation is performed on a second memory cell connected to the first word line and a second bit line included in the first storage block, a verification voltage is applied after the program voltage is applied to the second memory cell.

Embodiments of the disclosure may provide a storage device including a memory including a plurality of storage blocks, each of the plurality of storage blocks including a plurality of word lines, a plurality of bit lines, and a plurality of memory cells, and a controller configured to control a program operation for the memory, wherein, in a first period during which a program operation is performed on a first memory cell connected to a first word line included in a first storage block among the plurality of storage blocks, a program voltage is applied to the first memory cell, and the program operation on the first memory cell is completed without a verification voltage being applied to the first memory cell, and wherein, in a second period during which a program operation is performed on a second memory cell connected to a second word line included in the first storage block, a verification voltage is applied after the program voltage is applied to the second memory cell.

Embodiments of the disclosure may provide a storage device including a memory including a plurality of word lines, a plurality of bit lines and a plurality of memory cells, and a controller configured to control the memory, wherein a first program command and a second program command are transmitted to the memory by the controller, and a program operation is performed for a first period in response to the first program command, and a program operation is performed for a second period longer than the first period in response to the second program command.

According to embodiments of the present disclosure, it is possible to improve the performance and power consumption efficiency of an operation of writing data to a storage device, and increase the reliability of the operation of writing data.

### BRIEF DESCRIPTION OF THE DRAWINGS

FIG. 1 illustrates a schematic configuration of a storage device according to embodiments of the present disclosure.

FIG. 2 illustrates a configuration of a memory included in a storage device according to embodiments of the present disclosure.

FIG. 3 illustrates a structure of a memory cell array included in a memory of a storage device according to embodiments of the present disclosure.

FIG. 4 illustrates a configuration of a controller included in a storage device according to embodiments of the present disclosure.

FIGS. 5 to 7 illustrate examples of processes in which a storage device according to embodiments of the present disclosure performs a program operation.

FIG. 8 illustrates a process in which a storage device according to embodiments of the present disclosure performs a test operation.

FIGS. 9A and 9B illustrate examples of methods of performing a program operation for a storage block included in a storage device according to embodiments of the present disclosure.

FIG. 10 illustrates an example of voltages applied during a program operation for a storage block included in a storage device according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

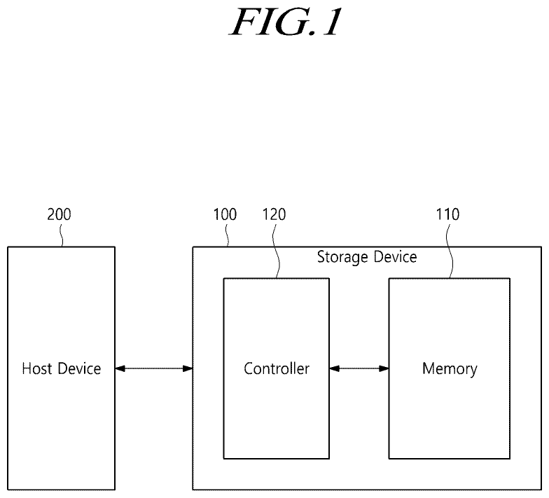

FIG. 1 illustrates a schematic configuration of a storage device 100 according to embodiments of the present disclosure.

Referring to FIG. 1, a storage device 100 according to embodiments of the present disclosure may include at least one memory 110. The storage device 100 may include a controller 120 for controlling the operation of the memory 110.

The memory 110 may be, for example, a volatile memory such as DRAM, SDRAM, DDR SDRAM, and LPDDR SDRAM, but the memory 110 according to embodiments of the present disclosure is not limited thereto. The memory 110 may also be a non-volatile memory such as a NAND flash memory, a 3D NAND flash memory, and a NOR flash memory. In addition, some of the memory 110 included in the storage device 100 may be volatile memory, and others may be non-volatile memory.

In addition, the memory 110 may be one of various types of memory, such as a resistive memory (e.g., ReRAM), a phase-change memory, a magnetoresistive memory, a ferroelectric memory, or a spin transfer torque-magnetic memory (e.g., SST-MRAM). In addition, the memory 110 may include a processing-in-memory component having an operation function or a data processing function, depending on the case.

The memory 110 may include a plurality of memory cells for storing data. Two or more memory cells may constitute one page. Two or more pages may constitute one unit storage area (e.g., a block).

The controller 120 may receive a command from the outside and control the operation of the memory 110 based on the received command. In addition, the controller 120 may control the operation of the memory 110 based on a command generated internally. In this specification, a command received from the outside by the controller 120 may be referred to as an external command, and a command generated internally by the controller 120 may be referred to as an internal command.

The controller 120 may control the operation of the memory 110 based on an external command or an internal command. The controller 120 may control, for example, an operation of writing data to the memory 110. The controller 120 may control an operation of reading data written to the memory 110. Data may be transmitted and received between the controller 120 and the memory 110.

The controller 120 may control a data preservation operation (e.g., a refresh operation, a patrol scrub operation, etc.) or an erase operation for data written to the memory 110 depending on the type of the memory 110.

The controller 120 may perform a background operation associated with the memory 110 based on an external command received from an external host device 200 or based on an internal command in order to maintain and improve the operating performance of the storage device 100. The background operation may include, for example, one or more of garbage collection, wear leveling, read reclaim, or bad block management operations. The controller 120 may improve the operating performance of the storage device 100 or prevent the operating performance from being deteriorated by controlling the background operation.

The controller 120 may control the operation of the memory 110 based on a command received from an external host device 200. The controller 120 may provide the host device 200 with a processing result according to an operation corresponding to the command. The controller 120 may transmit data or a response signal to the host device 200.

The host device 200 may be a computer, an ultra-mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a computer network, one of various electronic devices configuring a telematics network, an RFID (radio frequency identification) device, and a mobility device (e.g., a vehicle, a robot or a drone) capable of driving under human control or autonomous driving, as non-limiting examples. Alternatively, the host device 200 may be a virtual reality (VR) device providing 2D or 3D virtual reality images or an augmented reality (AR) device providing augmented reality images. In addition to the examples described above, the host device 200 may be any one of various electronic devices that require a storage device 100 capable of storing data.

The host device 200 may include at least one operating system (OS). The operating system may generally manage and control the function and operation of the host device 200, and may control interoperability between the host device 200 and the storage device 100. The operating system may be classified into a general operating system and a mobile operating system depending on the mobility of the host device 200.

The host device 200 and the controller 120 may be separate devices. In some cases, the controller 120 may be implemented as a single device integrated with the host device 200. In this case, the function of the controller 120 may be implemented by being included in the host device 200, and the memory system 100 may include only a memory controller 112 which directly controls the operation of the memory 111. In the following, for the convenience of explanation, it will be described as an example a case in which the controller 120 and the host device 200 are separated from each other.

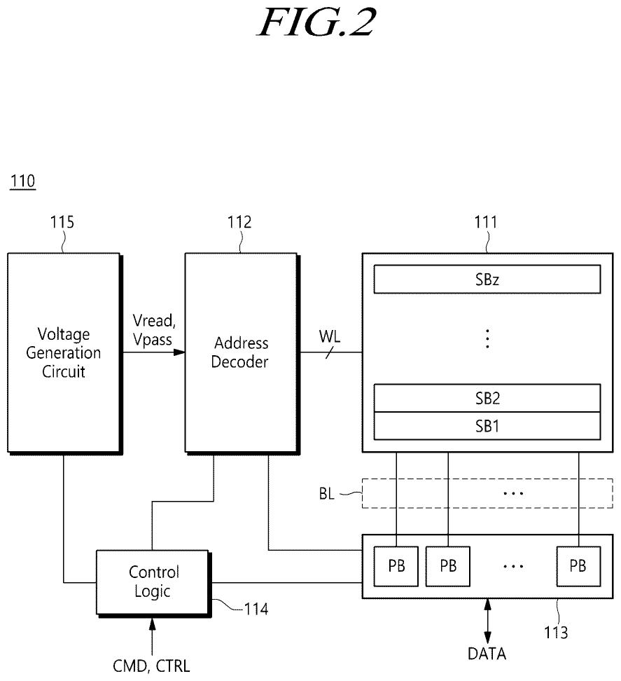

FIG. 2 illustrates a configuration of a memory 110 included in a storage device 100 according to embodiments of the present disclosure.

Referring to FIG. 2, the memory 110 according to the embodiments of the present disclosure may include a memory cell array 111, an address decoder 112, a read and write circuit 113, a control logic 114, and a voltage generation circuit 115.

The memory cell array 111 may include a plurality of storage blocks SB1 to SBz (where z is a natural number of 2 or more).

In the plurality of storage blocks SB, a plurality of word lines WL and a plurality of bit lines BL may be arranged, and a plurality of memory cells may be arranged. Two or more memory cells may constitute a page. The storage block SB may include a plurality of pages. An operation of writing or reading data may be performed in units of pages.

The plurality of storage blocks SB may be connected to the address decoder 112 through a plurality of word lines WL. The plurality of storage blocks SB may be connected to the read and write circuit 113 through the plurality of bit lines BL.

Each of the plurality of storage blocks SB may include a plurality of memory cells. The plurality of memory cells may be non-volatile memory cells and may be composed of non-volatile memory cells having a vertical channel structure.

The memory cell array 111 may be composed of a two-dimensional memory cell array, and in some cases, may be composed of a three-dimensional memory cell array.

Each of the plurality of memory cells included in the memory cell array 111 may store at least 1 bit of data. For example, each of the plurality of memory cells included in the memory cell array 111 may be a single-level cell (SLC) which stores 1 bit of data. As another example, each of the plurality of memory cells included in the memory cell array 111 may be a multi-level cell (MLC) which stores 2 bits of data, a triple-level cell (TLC) which stores 3 bits of data, a quad-level cell (QLC) which stores 4 bits of data, or a memory cell which stores 5 or more bits of data.

The number of bits of data stored in each of the plurality of memory cells may be determined dynamically. For example, a single-level cell storing 1 bit of data may be changed to a triple-level cell storing 3 bits of data.

The address decoder 112, the read and write circuit 113, the control logic 114, and the voltage generation circuit 115 may operate as peripheral circuits driving the memory cell array 111.

The address decoder 112 may be connected to the memory cell array 111 through a plurality of word lines WL. The address decoder 112 may be configured to operate in response to the control of the control logic 114.

The address decoder 112 may receive an address through an input/output buffer inside the memory 110. The address decoder 112 may be configured to decode a block address among the received addresses. The address decoder 112 may select at least one storage block SB according to the decoded block address.

The address decoder 112 may receive a read voltage Vread and a pass voltage Vpass from a voltage generation circuit 115.

The address decoder 112 may apply a program voltage for a program operation to a word line WL which is a target of the program operation during a program operation. The pass voltage Vpass may be applied to a word line WL other than the word line WL which is a target of the program operation. Data may be written to each memory cell according to the voltage supplied to the bit line BL connected to the word line WL to which the program voltage is applied.

The address decoder 112 may apply the read voltage Vread to the selected word line WL in the selected storage block SB during the read operation, and apply the pass voltage Vpass to the remaining non-selected word lines WL.

The address decoder 112 may apply the verification voltage generated by the voltage generation circuit 115 to the selected word line WL in the selected storage block SB during the program verification operation, and apply the pass voltage Vpass to the remaining non-selected word lines WL.

The address decoder 112 may be configured to decode a column address among the received addresses. The address decoder 112 may transmit the decoded column address to the read and write circuit 113.

The read operation and program operation of the memory 110 may be performed in page units. The address received when requesting the read operation and program operation may include one or more of a block address, a row address, and a column address.

The address decoder 112 may select one storage block SB and one word line WL according to the block address and the row address. The column address may be decoded by the address decoder 112 and provided to the read and write circuit 113.

The address decoder 112 may include one or more of a block decoder, a row decoder, a column decoder, and an address buffer.

The read and write circuit 113 may include a plurality of page buffers PB. The read and write circuit 113 may operate as a “read circuit” during a read operation of the memory cell array 111, and may operate as a “write circuit” during a write operation.

The read and write circuit 113 may also be referred to as a page buffer circuit or a data register circuit including a plurality of page buffers PB. The read and write circuit 113 may include a data buffer in charge of a data processing function, and may further include a cache buffer in charge of a caching function.

A plurality of page buffers PB may be connected to a memory cell array 111 through a plurality of bit lines BL. The plurality of page buffers PB may continuously supply sensing current to bit lines BL connected to memory cells in order to sense threshold voltages Vth of memory cells during a read operation and a program verification operation, and may detect a change in the amount of current flowing according to the program state of the corresponding memory cell through a sensing node and latch information on the change as sensing data.

The read and write circuit 113 may operate in response to page buffer control signals output from the control logic 114.

The read and write circuit 113 may sense data of a memory cell during a read operation, temporarily store the read data, and then output the data to the input/output buffer of the memory 110. As an illustrative embodiment, the read and write circuit 113 may include, in addition to page buffers PB or page registers, a column selection circuit, etc.

The control logic 114 may be connected to the address decoder 112, the read and write circuit 113, and the voltage generation circuit 115. The control logic 114 may receive a command CMD and a control signal CTRL through the input/output buffer of the memory 110.

The control logic 114 may be configured to control the overall operation of the memory 110 in response to the control signal. The control logic 114 may output a control signal for adjusting the pre-charge potential level of the sensing node of a plurality of page buffers PBs.

The control logic 114 may control the read and write circuit 113 to perform a read operation of the memory cell array 111. The voltage generation circuit 115 may generate a read voltage Vread and a pass voltage Vpass used during the read operation in response to a voltage generation circuit control signal output from the control logic 114.

Each of the storage blocks SB of the memory 110 may be composed of a plurality of pages corresponding to a plurality of word lines WL and a plurality of strings corresponding to a plurality of bit lines BL.

In the storage block SB, a plurality of word lines WL may be arranged crossing a plurality of bit lines BL. A memory cell connected to one of the plurality of word lines WL and one of the plurality of bit lines BL may be defined. A transistor may be arranged in each memory cell.

The transistor arranged in the memory cell may include a drain, a source, and a gate, etc. The drain (or source) of the transistor may be connected to the corresponding bit line BL directly or via another transistor. The source (or drain) of the transistor may be connected to the source line (which may be ground) directly or via another transistor. The gate of the transistor may include a floating gate surrounded by an insulator and a control gate to which a gate voltage is applied from a word line WL.

In each storage block SB, a selection line (also referred to as a source selection line or a drain selection line) may be further arranged outside the outermost word line WL that is closer to the read and write circuit (113) among the two outermost word lines (WL), and another selection line (also referred to as a drain selection line or a source selection line) may be further arranged outside the other outermost word line WL.

In some cases, one or more dummy word lines may be further arranged between the outermost word line and the selection line.

The read operation and program operation (e.g., write operation) of the storage block SB described above may be performed in units of pages, and the erase operation may be performed in units of storage blocks SB of the memory 110.

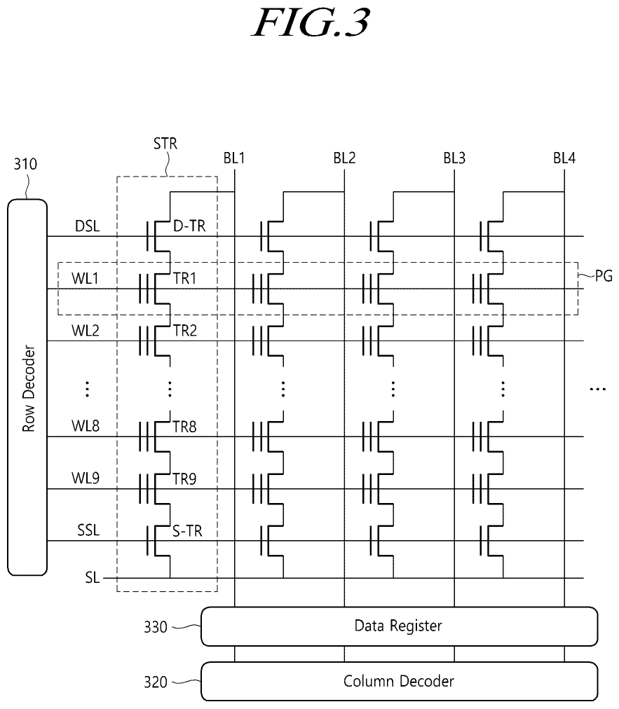

FIG. 3 illustrates an example of a structure of a memory cell array 111 included in a memory 110 of a storage device 100 according to embodiments of the present disclosure.

Referring to FIG. 3, the memory 110 may include a core region where memory cells are gathered and an auxiliary region where circuits for the operation of the memory cell array 111 are arranged, corresponding to the remaining region other than the core region.

A plurality of word lines WL1, . . . , WL9 and a plurality of bit lines BL1, . . . , BL4 may be arranged to cross each other in the core region. The number of word lines WL and the number of bit lines BL illustrated in FIG. 3 are examples, and the number of word lines WL and the number of bit lines BL included in each storage block (SB) may vary.

A plurality of word lines WL may be connected to a row decoder 310. A plurality of bit lines BL may be connected to a column decoder 320. A data register 330 corresponding to a read and write circuit 113 may be located between the plurality of bit lines BL and the column decoder 320.

Each of the plurality of word lines WL may correspond to a page. For example, as in the example illustrated in FIG. 3, each of the plurality of word lines WL may correspond to one page. In some cases, when the memory cell operates as a multi-level cell or a triple-level cell, each of the plurality of word lines WL may correspond to two or more pages. A page may be a minimum unit in which a program operation and a read operation are performed. All memory cells included in the same page may operate simultaneously during the program operation and the read operation.

The plurality of bit lines BL may be divided into, for example, odd-numbered bit lines BL and even-numbered bit lines BL, and may be connected to the column decoder 320. Each of the plurality of bit lines BL may correspond to a string.

The string may include a plurality of transistors TR1, . . . , TR9 connected to a plurality of word lines WL. An area where a plurality of transistors TR exist may correspond to a memory cell. The plurality of transistors TR may be transistors including a control gate and a floating gate, as described above.

The plurality of word lines WL may include two outermost word lines WL1 and WL9. A first selection line DSL may be arranged on the outside of a first word line WL1 that is located closer to the data register 330 in terms of a signal path among the two word lines WL1 and WL9. The first word line WL1 may be referred to as a first outermost word line. A second selection line SSL may be arranged on the outside of a ninth word line WL9 among the two word lines WL1 and WL9. The ninth word line WL9 may be referred to as the second outermost word line. In some cases, at least one dummy word line may be arranged between the first outermost word line and the first selection line DSL. At least one dummy word line may be arranged between the second outermost word line and the second selection line SSL.

A first selection transistor D-TR whose on/off is controlled by the first selection line DSL may include a gate electrode connected to the first selection line DSL. The first selection transistor D-TR may not include a floating gate. A second selection transistor S-TR whose on/off is controlled by the second selection line SSL may include a gate electrode connected to the second selection line SSL. The second select transistor S-TR may not include a floating gate.

The first selection transistor D-TR may perform a switch function to turn on or off the connection between the corresponding string and the data register 330. The second selection transistor S-TR may perform a switch function to turn on or off the connection between the corresponding string and the source line SL.

During a program operation, a predetermined turn-on voltage is applied to the gate electrode of the first selection transistor D-TR, and the first selection transistor D-TR may be turned on. A predetermined turn-off voltage may be applied to the gate electrode of the second selection transistor S-TR, and the second selection transistor S-TR may be turned off.

During a read operation or a verification operation, both the first selection transistor D-TR and the second selection transistor S-TR may be turned on. The current may flow through the string to the source line SL corresponding to the ground, and the voltage level of the bit line BL may be measured. During a read operation or a verification operation, there may be a time difference between the on and off timing of the first selection transistor D-TR and the second selection transistor S-TR.

During an erase operation, a predetermined voltage (e.g., 20 V) may be supplied to the substrate through the source line SL. During an erase operation, the first selection transistor D-TR and the second selection transistor S-TR may be floated. Electrons move due to the potential difference between the floating gate and the substrate, and data written in the memory cell may be erased.

In this way, a program operation, a read operation and an erase operation may be performed by driving the word line WL and the bit line BL included in the memory cell array 111. During program operation, it is possible to check whether data is written to each memory cell or each page through a verification operation which operates in a manner similar to a read operation.

In addition, in some cases, the verification operation may be performed only for some memory cells or some pages included in the memory cell array 111, thereby reducing the time required for the data program operation and improving the operational efficiency of the memory 110.

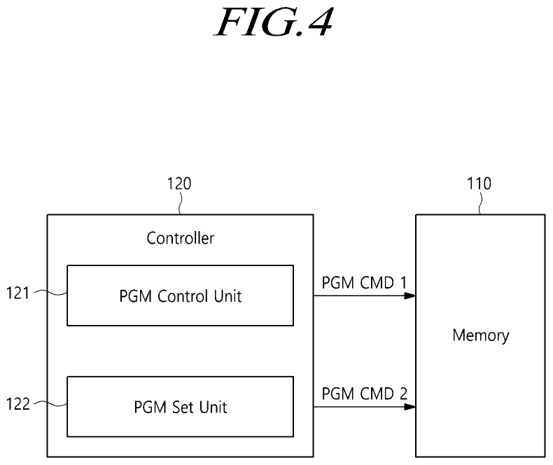

FIG. 4 illustrates an example of a configuration of a controller 120 included in a storage device 100 according to embodiments of the present disclosure.

Referring to FIG. 4, the controller 120 may include a program control unit 121 and a program set unit 122. The program control unit 121 and the program set unit 122 may be separately-configured circuits within the controller 120 or may be separate functional configurations of a single circuit.

The program control unit 121 and the program set unit 122 may set a program method for each memory cell, each page, or each string included in the memory 110, and may control a program operation according to the set program method.

As an example, the program control unit 121 may receive a command to write data from an external device such as a host device 200. The program control unit 121 may determine a physical address of the memory 110 to which a logical address received from the host device 200 is mapped. The program control unit 121 may select a method of programming the corresponding data according to the determined physical address. The program control unit 121 may select a method of programming the corresponding data based on information set by the program set unit 122, for example.

The program control unit 121 may generate a program command according to the selected program method and transmit the program command to the memory 110. The program control unit 121 may transmit the program command to the memory 110 and transmit data to be written according to the program command to the memory 110. The data to be written may be transmitted in a period corresponding to the period in which the program command is transmitted or in a different period.

The program control unit 121 may transmit a first program command or a second program command to the memory 110, for example.

The first program command may instruct an operation in which a program voltage but not a verification voltage is applied to the corresponding memory cell during a program operation for the memory 110. In response to receive the first program command, the memory 110 may perform the program operation by applying the program voltage to the corresponding memory cell according to the first program command, and may not perform the verification operation.

The second program command may instruct an operation in which the program voltage and the verification voltage are applied to the corresponding memory cell during a program operation for the memory 110. When receiving the second program command, the memory 110 may perform the program operation in which the program voltage is applied to the corresponding memory cell according to the second program command. Following that, the memory 110 may perform the verification operation by applying the verification voltage to the corresponding memory cell during the program operation.

When a program operation is performed according to the first program command, the program voltage but not the verification voltage is applied to the corresponding memory cell. When a program operation is performed according to the second program command, the program voltage and the verification voltage are applied to the corresponding memory cell, and the program operation may be performed.

A period corresponding to an amount of time needed to perform the program operation according to the first program command may be different from a period corresponding to an amount of time needed to perform the program operation according to the second program command. The period of the program operation according to the first program command may be shorter than the period of the program operation according to the second program command.

The program operation according to the first program command may reduce the time required for the program operation and improve the program performance. The program operation and verification operation according to the second program command may improve the reliability of the program operation for the memory cell.

The program set unit 122 may set a memory cell operating according to the first program command and a memory cell operating according to the second program command separately.

For example, the program set unit 122 may set a first storage block SB which operates according to the first program command and a second storage block SB which operates according to the second program command among the storage blocks SB included in the memory 110.

Alternatively, the program set unit 122 may set a first word line WL which operates according to the first program command and a second word line WL which operates according to the second program command among the word lines WL included in the storage block SB.

In addition, the program set unit 122 may set a first string which operates according to the first program command and a second string which operates according to the second program command among the strings corresponding to the bit lines (BL) included in the storage block SB.

The program set unit 122 may set a program operation method so that the program operation is performed by applying only the program voltage without a verification operation to improve the efficiency of the program operation for the memory 110.

The program set unit 122 may set a program operation method so that the program operation and the verification operation are performed only for a memory cell, a word line WL, or a bit line BL whose reliability may be lowered in the case where the program operation is performed without a verification operation.

The setting of the program operation method for each memory area of the memory 110 may be performed by detecting a memory area whose reliability is below a certain level through an initial test. Alternatively, during the operation of the memory 110, a memory area requiring verification operation may be detected by testing all or part of each memory area during a preset period, and there may be set a program operation method for each memory area. Alternatively, the memory area requiring verification operation may be determined based on a result of an operation of an error correcting code circuit. The need for the verification operation may be detected by monitoring the operation of the error correcting code circuit in the memory 110. For example, if the number of error bits encountered during ECC checking of a read approaches the limit of how may the ECC can correct, the memory area which the number of error bits approaches the limit may be detected as the memory area requiring verification operation.

The program control unit 121 may perform a program operation for the corresponding memory area differently based on the program operation method set by the program set unit 122.

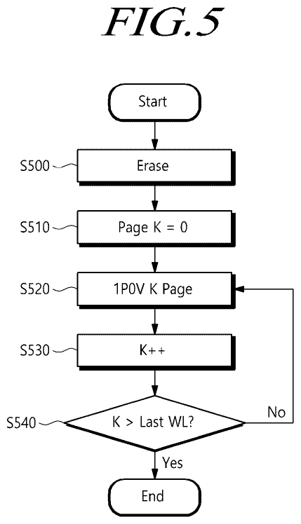

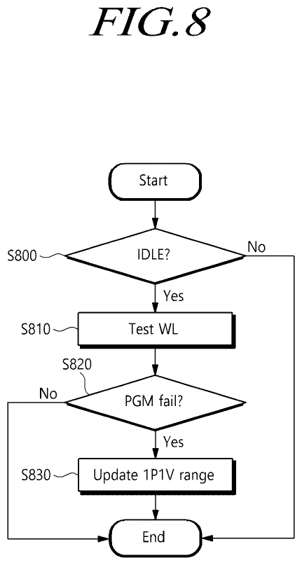

FIGS. 5 to 7 illustrate examples of a process in which a storage device 100 according to embodiments of the present disclosure performs a program operation. FIG. 8 illustrates an example of a process in which a storage device 100 according to embodiments of the present disclosure performs a test operation.

FIG. 5 illustrates an example in which a program operation is performed on a portion set as a memory area which does not require a verification operation in a storage block SB included in a storage device 100. In addition, there is illustrated the program operation method in which a program operation is performed on each page included in the memory 110.

The controller 120 may perform an erase operation on the storage block SB for a program operation on the storage block SB (S500). However, the erase operation is not always required and therefore may not always be performed.

The controller 120 may set the number K of a page which is a target of the program operation to 0 (S510), and perform a program operation on the page.

Since the program operation method for the page included in the storage block SB is set to perform only a program operation without a verification operation, the controller 120 may perform a program operation on the page according to a method of applying only a program voltage to the page (S520).

The controller 120 may increase K by 1 when the program operation for the corresponding page is completed (S530).

The controller 120 may check whether K is greater than the value of the last word line WL(S540). If K is less than or equal to the value of the last word line WL, the controller 120 may perform the program operation for the K-th page again, and if K is greater than the value of the last word line WL, the controller may terminate the program operation for the corresponding storage block SB.

The controller 120 may sequentially perform only the program operation for each page included in the storage block SB set as not requiring the verification operation, and may complete the program operation for the corresponding storage block SB. Since the program operation is performed without the verification operation, a period for performing the program for the corresponding storage block SB can be reduced.

In the case that a verification operation is required for at least some memory areas included in each storage block SB, the controller 120 may perform an operation of writing data to the corresponding memory area by separately applying the program operation method.

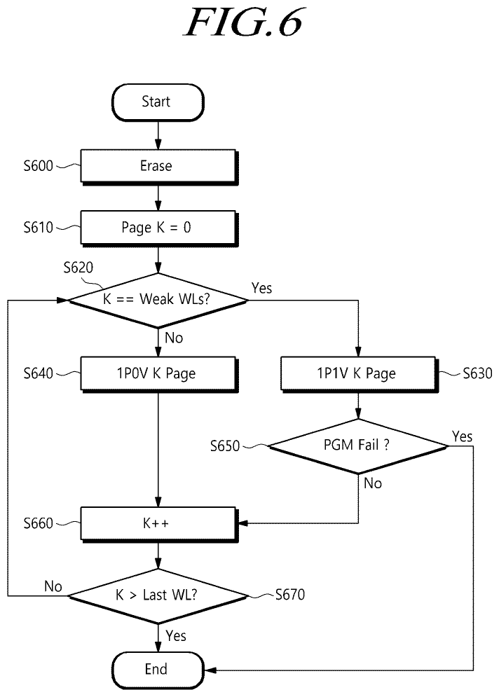

As an example, referring to FIG. 6, there is illustrated an example of a case where the controller 120 determines the program operation method separately for each word line WL included in the storage block SB.

The controller 120 may perform an erase operation on the storage block SB for the program operation (S600). The controller 120 may set the number K of a page which is a target of the program operation to 0 (S610). The controller 120 may check whether K indicates a page set as a word line WL for which a verification operation is required (S620).

If a verification operation is required for the corresponding page, the controller 120 may apply a program voltage to the corresponding page and then apply the verification voltage to perform the program operation (S630). If a verification operation is not required for the corresponding page, the controller 120 may apply only the program voltage to the corresponding page and perform the program operation (S640).

If it is determined that the program operation has failed through the verification operation (S650), the controller 120 can terminate the program operation or perform control to perform the program operation for the corresponding page again.

The controller 120 may increase the K value if it is determined that the program operation is normally performed through the verification operation or the program operation is terminated without the verification operation (S660). The controller 120 may check whether K corresponds to the last word line WL(S670), check a setting value of the program operation method for each word line WL, and perform the program operation or terminate the program operation for the corresponding storage block SB.

The controller 120 may perform the program operation method differently for each word line WL to reduce the time required for the program operation while maintaining the reliability of the program operation.

In addition, the controller 120 may perform the program operation method by dividing it for each string according to the set value of the program operation method.

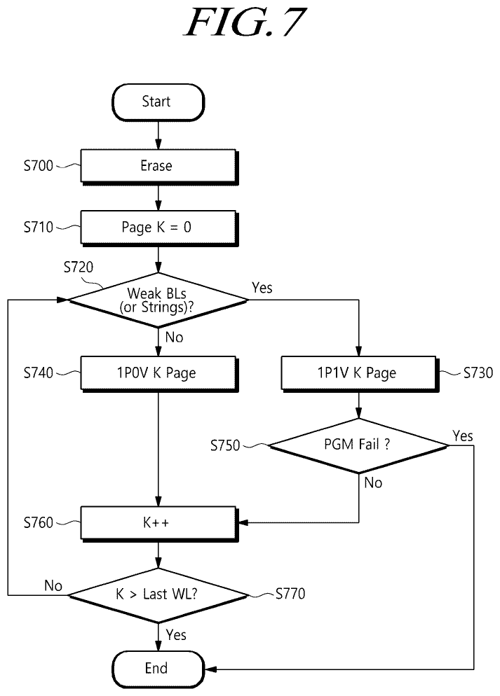

For example, referring to FIG. 7, the controller 120 may perform an erase operation on a storage block (SB) (S700), and set the number K of a page which is a target of the program operation to 0 (S710).

The controller 120 may check whether the bit line BL or string included in the page is a bit line BL requiring a verification operation during the program operation on the page (S720).

The controller 120 may control the application of the program voltage and the verification voltage to the corresponding memory area if the bit line BL or string requiring the verification operation is included, and may perform the program operation (S730). If it is determined that the program operation has failed through the verification operation (S750), the program operation may be terminated or the program operation for the corresponding memory area may be performed again.

The controller 120 may perform a program operation without a verification operation if a bit line BL corresponds to a bit line BL or string for which a verification operation is not required (S740).

The controller 120 may increase the K value (S760) and, terminate the program operation for the corresponding storage block SB when the program operation for the last word line WL is completed (S770).

The controller 120 may perform a program operation by applying only the program voltage based on the value set for each memory area, or perform a verification operation by applying a verification voltage after the program operation, thereby improving the efficiency of the program operation and maintaining the reliability of the program operation for a memory area with low reliability.

The controller 120 may set and manage values for the program operation method for each word line WL or each bit line BL, and, in some cases, may update the set values for the program operation method through a test operation.

For example, referring to FIG. 8, the controller 120 may check whether there is an idle period in which no command is received from the host device 200 or an operation for controlling the memory 110 is not performed according to a command of the host device 200 (S800).

The controller 120 may perform a test operation on a specific word line WL during the idle period (S810). The controller 120 may, for example, write data to a memory area corresponding to a specific word line WL and check whether the program operation is successful to perform the test.

The controller 120 may perform a test operation on a memory area corresponding to a word line WL set as not requiring a verification operation. Alternatively, the controller 120 may perform a test on some representative word lines WL among the word lines WL included in each storage block SB. In addition, the controller 120 may test whether a verification operation is required for the corresponding storage block SB by using a selection line or a dummy line located outside the word line WL included in each storage block SB. If the program operation fails according to the result of the test operation (S820), the controller 120 may update the memory area corresponding to the corresponding word line WL to a memory area requiring a verification operation (S830). In some cases, the controller 120 may update a memory area corresponding to a specific word line WL or corresponding to a specific bit line BL as a memory area requiring a verification operation.

The controller 120 may manage only some memory areas as memory areas requiring a verification operation, and update the memory area requiring a verification operation through a test according to the operation period of the memory 110, thereby maintaining the efficiency of the program operation and preventing the reliability of the program operation from deteriorating.

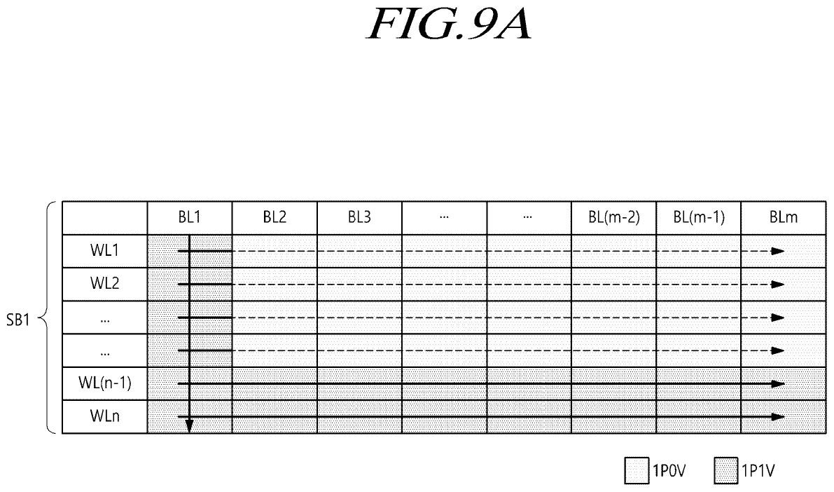

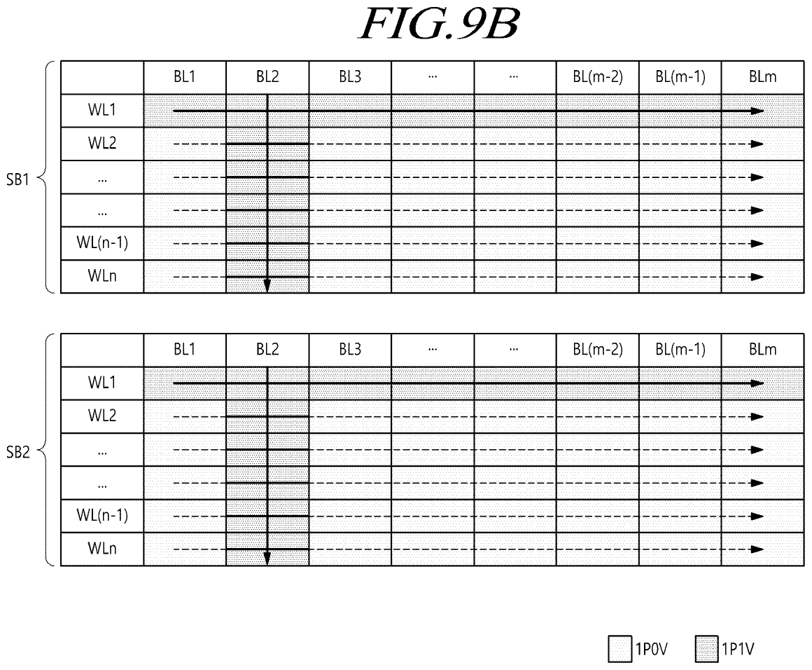

FIGS. 9A and 9B illustrate examples of a method of performing a program operation for a storage block SB included in a storage device 100 according to embodiments of the present disclosure.

FIG. 9A illustrates a case where a program operation is performed for a first storage block SB1. The first storage block SB1 may include, for example, n word lines WL and m bit lines BL.

FIG. 9A illustrates an example of a method in which a program operation is performed separately for each word line WL and each bit line BL, but the embodiments of the present disclosure may be similarly applied to a case in which a program operation is performed separately for each page configured by each word line WL and a plurality of bit lines BL.

As an example, the controller 120 may perform a program operation in which a program voltage is applied and a verification operation in which a verification voltage is applied when a program operation is performed for a memory cell connected to a first word line WL1 and a first bit line BL1, and may perform an operation of writing data to the corresponding memory cell.

The controller 120 may only perform a program operation in which a program voltage is applied to a memory cell connected to a first word line WL1 and a second bit line BL2, and may terminate the program operation without performing a verification operation for the corresponding memory cell.

The controller 120 may perform a program operation in which a program voltage is applied and a verification operation in which a verification voltage is applied for a memory cell connected to a second word line WL2 and a first bit line BL1, and may write data to the corresponding memory cell. The controller 120 may only perform a program operation in which a program voltage is applied for a memory cell connected to the second word line WL2 and the second bit line BL2 without a verification operation, and may write data.

In this way, the controller 120 may perform a program operation by applying a program operation method separately for each bit line BL, each string, or each page connected to different bit lines BL.

In addition, the controller 120 may control a program operation while performing a verification operation for all memory cells connected to a specific word line WL in the first storage block SB1.

As an example, the controller 120 may perform a program operation and a verification operation for a memory cell connected to the (n−1)-th word line WL(n−1) and the first bit line BL1, and a memory cell connected to the (n−1)-th word line WL(n−1) and the second bit line BL2, and may write data to the corresponding memory cells.

The controller 120 may also perform a program operation and a verification operation, and write data to a memory cell connected to the n-th word line WLn.

The verification operation may be selectively performed by page or string included in the same storage block SB by the controller 120. Accordingly, it is possible to improve the performance of the program operation and maintain the reliability of the program operation for the memory cell with low reliability.

In embodiments, the memory cell on which the verification operation is performed by the controller 120 may be independently set for each storage block SB.

As an example, referring to FIG. 9B, the controller 120 may perform a verification operation on a memory cell connected to the first word line WL1 among the word lines WL included in the first storage block SB1, and write data. The controller 120 may perform a verification operation on a memory cell connected to the second bit line BL2 among the bit lines BL included in the first storage block SB1, and write data. The memory cell connected to the second bit line BL2 may mean a second page group among the pages in the column direction included in the first storage block SB1.

The controller 120 may perform a verification operation only for some pages and some strings of the first storage block SB1, and perform a program operation without a verification operation for the remaining memory cells.

In addition, the controller 120 may perform a verification operation and write data for, for example, a memory cell connected to the first word line WL1 and a memory cell connected to the second bit line BL2 in a second storage block SB2. The controller 120 may write data without a verification operation for the remaining memory cells included in the second storage block SB2.

The position of the page or string on which the verification operation is performed in the second storage block SB2 may correspond to the position of the page or string on which the verification operation is performed in the first storage block SB1.

Alternatively, in some cases, the memory area where the verification operation is performed in the second storage block SB2 may be different from the memory area where the verification operation is performed in the first storage block SB1.

Alternatively, initially, the memory area where the verification operation is performed in the second storage block SB2 and the memory area where the verification operation is performed in the first storage block SB1 may be the same. Then, after the test is performed during the operation, the memory area where the verification operation is performed in the second storage block SB2 and the memory area where the verification operation is performed in the first storage block SB1 may be set differently.

Since the verification operation is selectively performed for each memory area included in the storage block SB by the controller 120, it is possible to maintain the reliability of the program operation and improve the efficiency of the program operation.

In addition, the time required for the program operation may differ depending on whether the verification operation is performed or not, so that the time required for the program operation can be reduced by skipping of the verification operation.

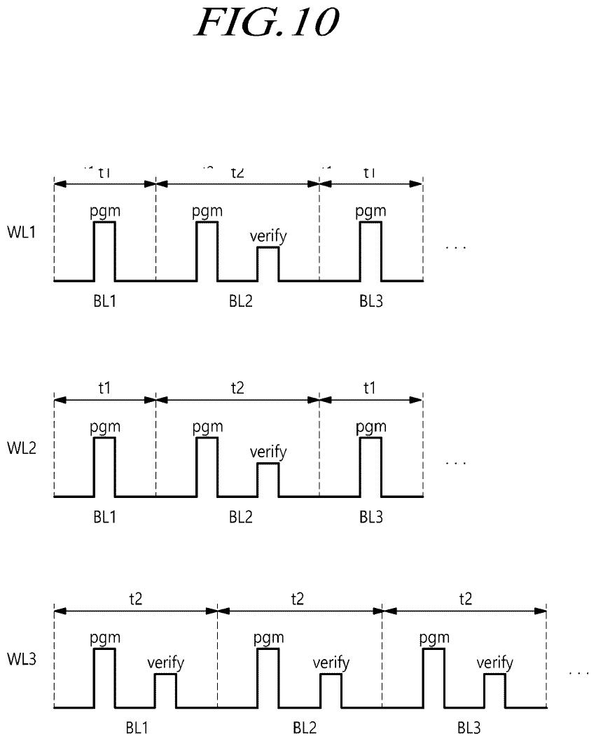

FIG. 10 illustrates an example of a voltage applied during a program operation for a storage block SB included in a storage device 100 according to embodiments of the present disclosure.

Referring to FIG. 10, only a program voltage may be applied to a memory cell operated by a first word line WL1 and a first bit line BL1 for a first period t1, and the program operation may be terminated. The program voltage and a verification voltage may be applied to a memory cell operated by the first word line WL1 and a second bit line BL2 for a second period t2, and the program operation may be performed. Only the program voltage may be applied to a memory cell operated by the first word line WL1 and a third bit line BL3 for a first period t1, and the program operation may be terminated.

Each of the first bit line BL1, the second bit line BL2, and the third bit line BL3 may mean a page including two or more bit lines BL.

Depending on whether a verification operation is performed, the period of a program operation required for the corresponding bit line BL may be different between the first period t1 and the second period t2. A length of the first period t1 may be shorter or less than a length of the second period t2.

The program operation for a memory cell connected to the second word line WL2 may be performed similarly to the program operation for the memory cell connected to the first word line WL1.

Since the program operation method may be set differently for each word line WL, the program operation for the memory cell connected to a third word line WL3 may be performed differently from the program operation for the memory cell connected to the first word line WL1 and the second word line WL2.

For example, the program voltage and the verification voltage may be applied to each memory cell connected to the third word line WL3, and the program operation may be performed.

The verification operation may be performed for all memory cells connected to the third word line WL3 to confirm that data has been written.

The length of a period during which the program operation is performed for all memory cells connected to the first word line WL1 or the second word line WL2 may be different from the length of a period during which the program operation is performed for all memory cells connected to the third word line WL3.

The controller 120 may control the length of the period required for the program operation differently and selectively perform a verification operation, thereby improving the performance and reliability of the program operation.

In addition, the controller 120 may control the period of the program operation so as to support a cache program operation even if the length of the period required for the program operation is set differently for each word line WL or each bit line BL.

As an example, the controller 120 may sequentially transmit a first program command instructing to perform only the program operation, a second program command instructing to perform the program operation and the verification operation, and a first program command instructing to perform only the program operation to the memory 110.

The controller 120 may transmit input data according to the 1^{st} first program command to the memory 110 during the period in which the second program command is transmitted. The controller 120 may transmit other input data according to the second program command to the memory 110 during the period in which the 2^{nd} first program command is transmitted. The length of the period in which the input data according to the 1^{st} first program command is transmitted may be the same as the length of the period in which the other input data according to the second program command is transmitted.

Even if the length of the first period t1, which is the program operation period according to the first program command, and the length of the second period t2, which is the program operation period according to the second program command, are different, the length of the period in which the input data is transmitted may be maintained the same. In addition, the first period t1 and the second period t2 may be set so that the input data can be transmitted within the transmission period of the program command. Even if the program operation period is set differently depending on the presence or absence of a verification operation, the program operation may be performed efficiently by supporting the cache program operation.

Based on embodiments of the disclosed technology described above, the operation delay time of the memory system may be advantageously reduced or minimized. In addition, based on an embodiment of the disclosed technology, an overhead occurring in the process of calling a specific function may be advantageously reduced or minimized. Although various embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope of the invention as defined in the following claims.

What is claimed is:

1. A storage device comprising:
a memory including a plurality of storage blocks, each of the plurality of storage blocks including a plurality of word lines, a plurality of bit lines, and a plurality of memory cells; and
a controller configured to control a program operation for the memory,
wherein, in a first period during which a program operation is performed on a first memory cell connected to a first word line and a first bit line included in a first storage block among the plurality of storage blocks, a program voltage is applied to the first memory cell, and the program operation on the first memory cell completes without a verification voltage being applied to the first memory cell,
wherein, in a second period during which a program operation is performed on a second memory cell connected to the first word line and a second bit line included in the first storage block, a verification voltage is applied after the program voltage is applied to the second memory cell.

2. The storage device of claim 1, wherein a length of the first period is different from a length of the second period.

3. The storage device of claim 1, wherein, in a third period during which a program operation is performed on a third memory cell connected to a second word line and the first bit line included in the first storage block, the program voltage is applied to the third memory cell, and the program operation on the third memory cell is terminated,
wherein, in a fourth period during which a program operation is performed on a fourth memory cell connected to the second word line and the second bit line included in the first storage block, the verification voltage is applied after the program voltage is applied to the fourth memory cell.

4. The storage device of claim 3, wherein a length of the third period is different from a length of the fourth period.

5. The storage device of claim 3, wherein a length of the third period is equal to a length of the first period, and a length of the fourth period is equal to a length of the second period.

6. The storage device of claim 3, wherein, in a fifth period during which a program operation is performed on a fifth memory cell connected to a third word line and the first bit line included in the first storage block, the program voltage is applied to the fifth memory cell, and then the verification voltage is applied,
wherein, in a sixth period during which a program operation is performed on a sixth memory cell connected to the third word line and the second bit line included in the first storage block, the program voltage is applied to the sixth memory cell, and then the verification voltage is applied.

7. The storage device of claim 6, wherein a length of the fifth period is equal to a length of the sixth period and is different from a length of the first period.

8. The storage device of claim 6, wherein a length of a period required for a program operation for all memory cells connected to the first word line is different from a length of a period required for a program operation for all memory cells connected to the third word line.

9. The storage device of claim 1, wherein, during a period in which a program operation is performed on all memory cells connected to at least one word line included in a second storage block among the plurality of storage blocks, only the program voltage is applied to all the memory cells without applying the verification voltage.

10. The storage device of claim 1, wherein, when a program operation is performed on a portion of the memory cells connected to at least one word line included in a second storage block among the plurality of storage blocks, only the program voltage is applied, and when a program operation is performed on the remaining memory cells, the program voltage and the verification voltage are applied.

11. The storage device of claim 10, wherein a position of the at least one word line included in the second storage block corresponds to a position of the first word line included in the first storage block.

12. The storage device of claim 1, wherein a test operation is performed on at least one word line included in the first storage block during a period other than a period during which the program operation is performed, and after the test operation, at least a portion of the memory cells to which the verification voltage is applied is changed.

13. The storage device of claim 1, wherein a test operation is performed on at least one selection line located between the plurality of word lines included in the first storage block during a period other than a period during which the program operation is performed, and after the test operation, at least a portion of the memory cells to which the verification voltage is applied is changed.

14. The storage device of claim 1, wherein the controller transmits input data to the memory during the first period and transmits other input data to the memory during the second period,
wherein a length of the period during which the input data is transmitted is equal to a length of the period during which the other input data is transmitted.

15. A storage device comprising:
a memory including a plurality of storage blocks, each of the plurality of storage blocks including a plurality of word lines, a plurality of bit lines, and a plurality of memory cells; and
a controller configured to control a program operation for the memory,
wherein, in a first period during which a program operation is performed on a first memory cell connected to a first word line included in a first storage block among the plurality of storage blocks, a program voltage is applied to the first memory cell, and the program operation on the first memory cell is completed without a verification voltage being applied to the first memory cell,
wherein, in a second period during which a program operation is performed on a second memory cell connected to a second word line included in the first storage block, a verification voltage is applied after the program voltage is applied to the second memory cell.

16. The storage device of claim 15, wherein, in each period during which a program operation is performed on all memory cells connected to the first word line, only the program voltage is applied to each of the memory cells.

17. The storage device of claim 15, wherein, in each period during which a program operation is performed on all memory cells connected to the second word line, the program voltage and the verification voltage are applied to each of the memory cells.

18. The storage device of claim 15, wherein a length of the first period is less than a length of the second period.

19. A storage device comprising:
a memory including a plurality of word lines, a plurality of bit lines and a plurality of memory cells; and
a controller configured to control the memory,
wherein a first program command and a second program command are transmitted to the memory by the controller, and a program operation is performed for a first period in response to the first program command, and a program operation is performed for a second period longer than the first period in response to the second program command.

20. The storage device of claim 19, wherein the controller transmits input data to the memory during the first period and transmits other input data to the memory during the second period,
wherein a length of the period during which the input data is transmitted is equal to a length of the period during which the other input data is transmitted.
